(19) United States
(12) Patent Application Publication
(10) Pub. No.: US 2023/0082341 A1
(43) Pub. Date: Mar. 16, 2023

(54) BAFFLE ASSEMBLY

(71) Applicants: Inventec (Pudong) Technology Corporation, Shanghai (CN); INVENTEC CORPORATION, Taipei City (TW)

(72) Inventor: Hong-You CHOU, Taipei City (TW)

(21) Appl. No.: 17/448,355

(22) Filed: Sep. 22, 2021

(30) Foreign Application Priority Data
Sep. 10, 2021 (CN) 202111064029.2

(51) Int. Cl. H05K 7/18; H05K 7/14

(52) U.S. Cl. CPC H05K 7/18; H05K 7/1461

(57) ABSTRACT

A baffle assembly includes a frame, a protruding piece and a baffle structure. The frame is configured to accommodate some expansion cards. The frame includes a first surface and a second surface adjacent to the first surface. The first surface has an opening configured to allow the expansion cards to enter into the frame. The protruding piece protrudes from the first surface. The baffle structure includes a first blocking plate and a second blocking plate. The first blocking plate is configured to abut against the first surface and at least partially cover the opening. The first blocking plate has a through hole. The through hole extends along a first direction. The protruding piece at least partially penetrates through the through hole. The second blocking plate is connected with the first blocking plate along the first direction and is configured to abut against the second surface.

### CROSS-REFERENCE TO RELATED APPLICATION

This application claims priority to China Application Serial Number 202111064029.2, filed Sep. 10 2021, which is herein incorporated by reference in its entirety.

### BACKGROUND

### Technical Field

The present disclosure relates to baffle assemblies. More particularly, the present disclosure relates to baffle assemblies for blocking expansion cards.

### Description of Related Art

With regard to the improvement of living standards of people, the demand of people for computer equipment has also been increasing. Correspondingly, in order to fulfill the increasing demand of the consumers, the manufacturers have been working hard to improve the computer equipment.

Apart from improving the operational efficiency of computer equipment, for example, the method to further secure the internal components of computer equipment while keeping a low cost is undoubtedly an important issue which the industry highly concerns.

### SUMMARY

A technical aspect of the present disclosure is to provide a baffle assembly, which can allow a user to install the baffle structure to the frame easily by bare hands, such that the expansion cards inside the frame can be protected and blocked.

According to an embodiment of the present disclosure, a baffle assembly includes a frame, at least one protruding piece and a baffle structure. The frame is configured to accommodate a plurality of expansion cards. The frame includes a first surface and a second surface adjacent to the first surface. The first surface has an opening configured to allow the expansion cards to enter into the frame. The protruding piece protrudes from the first surface. The baffle structure includes a first blocking plate and a second blocking plate. The first blocking plate is configured to abut against the first surface and at least partially cover the opening. The first blocking plate has at least one through hole. The through hole extends along a first direction. The protruding piece at least partially penetrates through the through hole. The second blocking plate is connected with the first blocking plate along the first direction and is configured to abut against the second surface.

In one or more embodiments of the present disclosure, the first surface and the second surface form a first angle. The first blocking plate and the second blocking plate form a second angle. The first angle is substantially equal to the second angle.

In one or more embodiments of the present disclosure, the first angle and the second angle are respectively 90 degrees.

In one or more embodiments of the present disclosure, the first blocking plate and the second blocking plate are connected with each other along a connecting line. The connecting line extends along a second direction. The second direction is perpendicular to the first direction.

In one or more embodiments of the present disclosure, the through hole has a first subsidiary through hole and a second subsidiary through hole communicated with the first subsidiary through hole. The second subsidiary through hole is located between the first subsidiary through hole and the second blocking plate along the first direction. The first subsidiary through hole is at least partially a circular hole. The second subsidiary through hole is at least partially a long hole extending along the first direction.

In one or more embodiments of the present disclosure, the second subsidiary through hole has a width along a second direction perpendicular to the first direction. The first subsidiary through hole has a diameter. The diameter is longer than the width.

In one or more embodiments of the present disclosure, the protruding piece includes a head portion and a rod portion. The rod portion is connected between the head portion and the frame. A first outer dimension of the head portion is shorter than the diameter and longer than the width. A second outer dimension of the rod portion is substantially equal to the width.

In one or more embodiments of the present disclosure, the baffle structure further includes a buckling portion. The buckling portion is configured to buckle with the frame. The buckling portion is connected with the first blocking plate. The first blocking plate is at least partially located between the second blocking plate and the buckling portion along the first direction.

In one or more embodiments of the present disclosure, the buckling portion is at least partially of a hook shape and is configured to buckle with an edge of the first surface.

In one or more embodiments of the present disclosure, a quantity of the protruding piece and a quantity of the through hole are respectively plural.

When compared with the prior art, the above-mentioned embodiments of the present disclosure have at least the following advantage:

(1) Since no additional tools are involved in the process to install the baffle structure to the frame or in the process to detach the baffle structure from the frame, the user can easily finish these processes by his/her bare hands, which is convenient to the user.

(2) Since no additional locking components such as screws are involved in the process to secure the baffle structure to the frame, apart from a saving of material cost, the time taken for the installation or the detachment of the baffle structure is also reduced.

(3) Since the first blocking plate of the baffle structure abuts against the first surface of the frame and at least partially covers the opening, the expansion cards located inside the frame are protected and blocked by the first blocking plate. Therefore, the expansion cards will not be loosened from the frame. Moreover, the first blocking plate facilitates a better effect of wind guiding and heat dissipation to the expansion cards.

### BRIEF DESCRIPTION OF THE DRAWINGS

The disclosure can be more fully understood by reading the following detailed description of the embodiments, with reference made to the accompanying drawings as follows:

FIG. 1 is a schematic view of a baffle assembly according to an embodiment of the present disclosure, in which the baffle structure and the frame are separated from each other;

FIG. 2 is a three-dimensional back view of the baffle structure of FIG. 1;

FIG. 3 is a front view of the through hole of FIG. 1;

FIG. 4 is a schematic view of a process of installing the baffle structure to the frame of FIG. 1;

FIG. 5 is a partial sectional view along the section line A-A of FIG. 4;

FIG. 6 is a schematic view of the baffle assembly of FIG. 1, in which the baffle structure is already installed to the frame; and

FIG. 7 is a partial sectional view along the section line B-B of FIG. 6.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

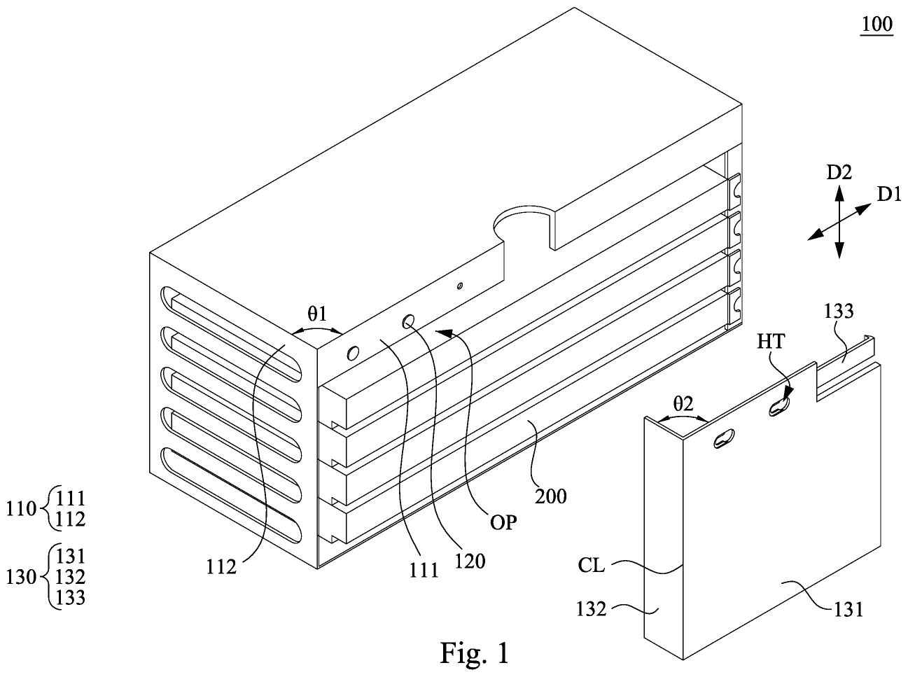

Reference is made to FIG. 1. FIG. 1 is a schematic view of a baffle assembly 100 according to an embodiment of the present disclosure, in which the baffle structure 130 and the frame 110 are separated from each other. In this embodiment, as shown in FIG. 1, a baffle assembly 100 includes a frame 110, at least one protruding piece 120 and a baffle structure 130. The frame 110 is configured to accommodate a plurality of expansion cards 200. The frame 110 includes a first surface 111 and a second surface 112 adjacent to the first surface 111. The first surface 111 has an opening OP. The opening OP is configured to allow the expansion cards 200 to enter into the frame 110. In practical applications, the expansion cards 200 can be peripheral component interconnect express (PCIE) cards. However, this does not intend to limit the present disclosure. Moreover, the protruding piece 120 protrudes from the first surface 111 of the frame 110.

In one embodiment of the present disclosure, the baffle assembly 100 can be applied to a server device, and this server device can be applied to, for example, computing by artificial intelligence (AI) or edge computing. Moreover, the server device can also be used as a 5G server, a cloud server or an internet server for vehicles.

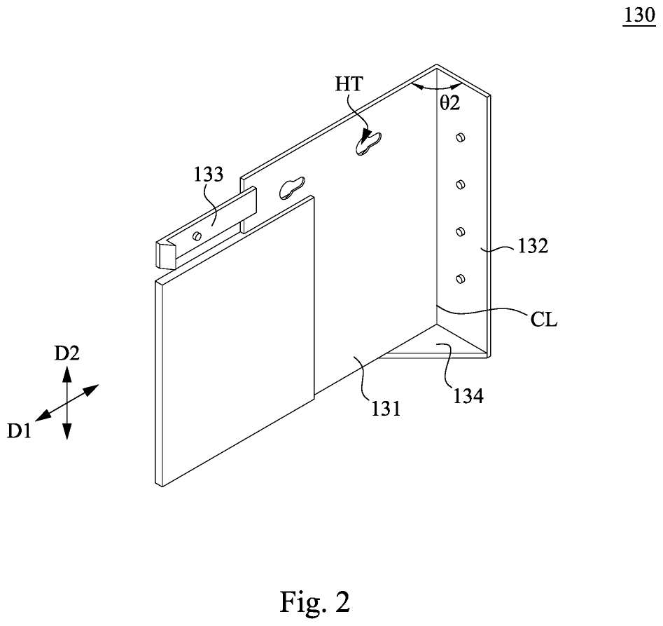

Reference is made to FIG. 2. FIG. 2 is a three-dimensional back view of the baffle structure 130 of FIG. 1. In this embodiment, as shown in FIGS. 1-2, the baffle structure 130 includes a first blocking plate 131 and a second blocking plate 132. The first blocking plate 131 is configured to abut against the first surface 111 of the frame 110 and at least partially cover the opening OP. The first blocking plate 131 has at least one through hole HT. The through hole HT extends along a first direction D1. The protruding piece 120 is configured to at least partially penetrate through the through hole HT. The second blocking plate 132 is connected with the first blocking plate 131 along the first direction D1 and is configured to abut against the second surface 112 of the frame 110.

Furthermore, as shown in FIGS. 1-2, the first blocking plate 131 and the second blocking plate 132 of the baffle structure 130 are connected with each other along a connecting line CL. The connecting line CL extends along a second direction D2. The second direction D2 is perpendicular to the first direction D1.

In addition, as shown in FIGS. 1-2, the first surface 111 and the second surface 112 of the frame 110 form a first angle θ1. The first blocking plate 131 and the second blocking plate 132 of the baffle structure 130 form a second angle θ 2. The first angle θ1 is substantially equal to the second angle θ 2. In practical applications, for example, the first angle and the second angle are respectively 90 degrees. However, this does not intend to limit the present disclosure. Moreover, as shown in FIG. 2, the baffle structure 130 further includes a supporting portion 134. The supporting portion 134 is at least partially shaped as a plate and is connected with the first blocking plate 131 and the second blocking plate 132 in a substantially perpendicular manner. Thus, the structural strength of the baffle structure 130 is enhanced, and the second angle θ2 formed by the first blocking plate 131 and the second blocking plate 132 is maintained.

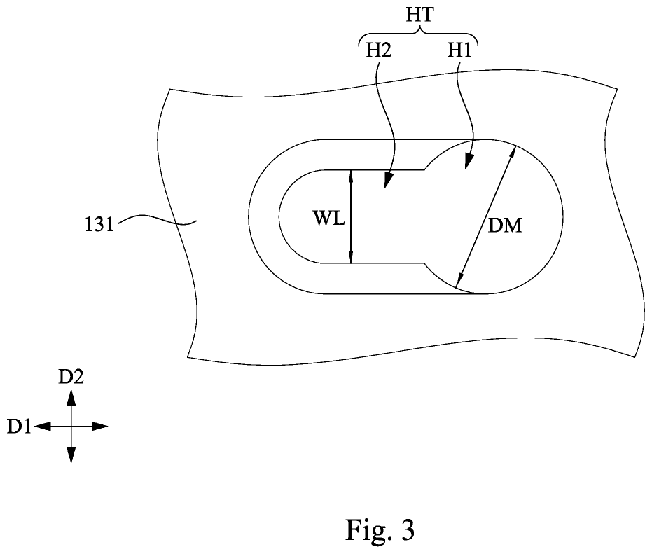

Reference is made to FIG. 3. FIG. 3 is a front view of the through hole HT of FIG. 1. In this embodiment, as shown in FIG. 3, the through hole HT has a first subsidiary through hole H1 and a second subsidiary through hole H2 communicated with the first subsidiary through hole H1. The second subsidiary through hole H2 is located between the first subsidiary through hole H1 and the second blocking plate 132 (please see FIGS. 1-2 for the second blocking plate 132) along the first direction D1. In addition, the first subsidiary through hole H1 and the second subsidiary through hole H2 are at least partially overlapped with each other. To be specific, the first subsidiary through hole H1 is at least partially a circular hole, while the second subsidiary through hole H2 is at least partially a long hole extending along the first direction D1. Since the first subsidiary through hole H1 and the second subsidiary through hole H2 are at least partially overlapped with each other, the circular profile of the first subsidiary through hole H1 is incomplete.

Furthermore, as shown in FIG. 3, the second subsidiary through hole H2 has a width WL along a second direction D2. The first subsidiary through hole H1 has a diameter DM. The diameter DM of the first subsidiary through hole H1 is longer than the width WL of the second subsidiary through hole H2.

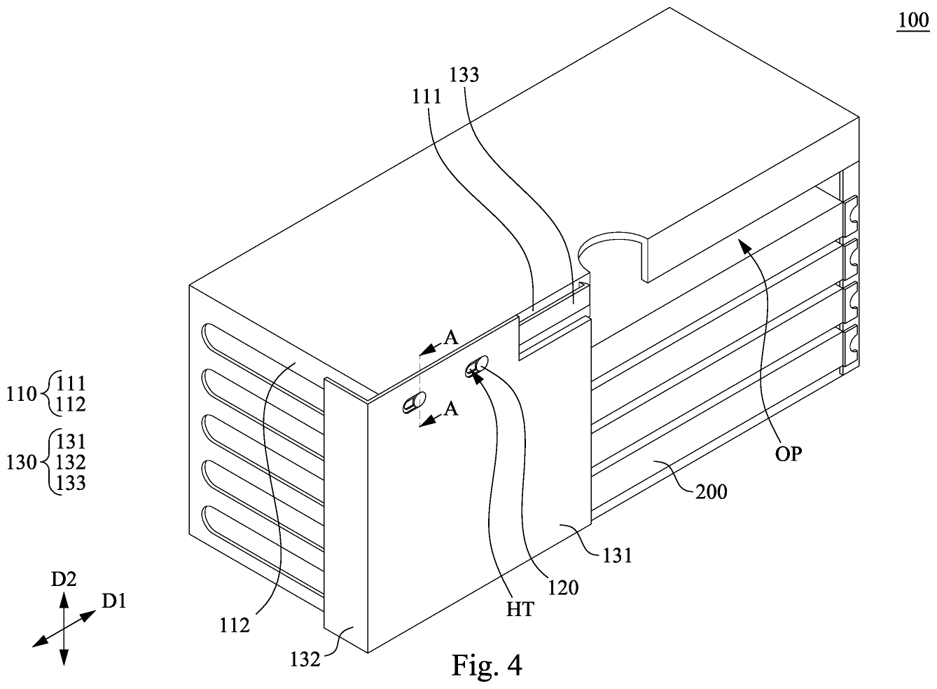

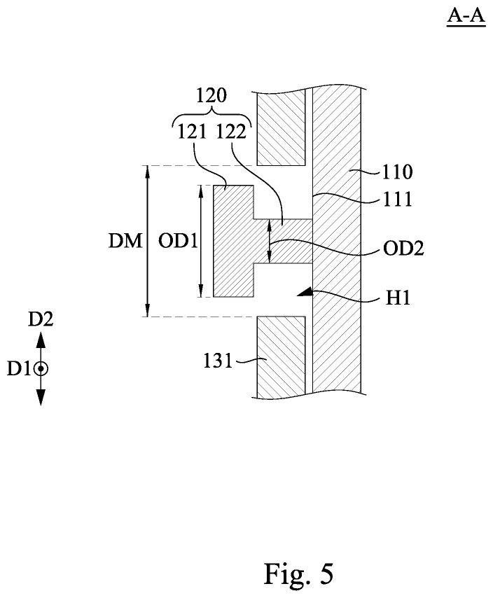

Reference is made to FIGS. 4-5. FIG. 4 is a schematic view of a process of installing the baffle structure 130 to the frame 110 of FIG. 1. FIG. 5 is a partial sectional view along the section line A-A of FIG. 4. When the baffle structure 130 is going to be installed to the frame 110, as shown in FIG. 4, the user first uses the protruding piece 120 to penetrate through the through hole HT of the first blocking plate 131, and abuts the first blocking plate 131 to the first surface 111 of the frame 110. As shown in FIG. 5, the protruding piece 120 includes a head portion 121 and a rod portion 122. The rod portion 122 is connected between the head portion 121 and the frame 110. A first outer dimension OD1 of the head portion 121 is shorter than the diameter DM of the first subsidiary through hole H1. Thus, the head portion 121 can penetrate through the first subsidiary through hole H1 of the first blocking plate 131. To be specific, the first outer dimension OD1 can be an outer diameter of the head portion 121 of a circular shape.

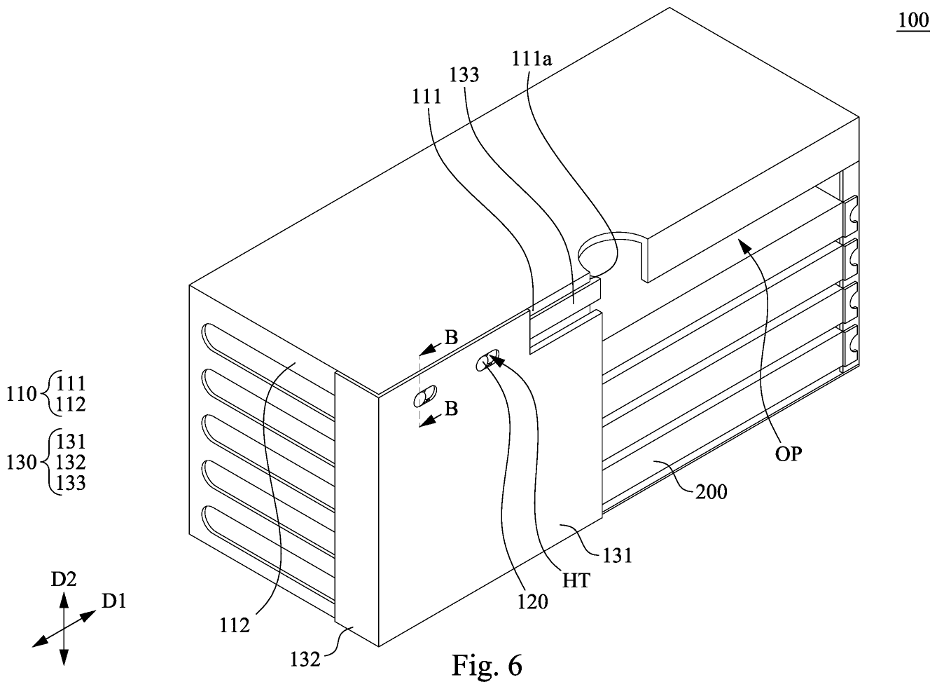

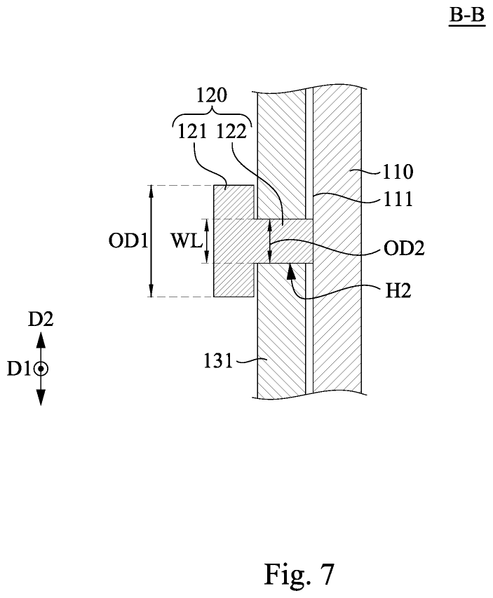

Reference is made to FIGS. 6-7. FIG. 6 is a schematic view of the baffle assembly 100 of FIG. 1, in which the baffle structure 130 is already installed to the frame 110. FIG. 7 is a partial sectional view along the section line B-B of FIG. 6. In this embodiment, as shown in FIG. 6, under the situation that the protruding piece 120 is penetrating through the first subsidiary through hole H1, the user moves the baffle structure 130 relative to the frame 110 along the first direction D1, such that the second blocking plate 132 abuts against the second surface 112 of the frame 110. Under this condition, as shown in FIG. 7, the rod portion 122 of the protruding piece 120 is located in the second subsidiary through hole H2. Moreover, a second outer dimension OD2 of the rod portion 122 is substantially equal to the width WL of the second subsidiary through hole H2. Thus, the rod portion 122 can secure the position of the baffle structure 130 relative to the frame 110 in the second direction D2. To be specific, the second outer dimension OD2 can be an outer diameter of the rod portion 122 shaped as a circular column. In addition, the first outer dimension OD1 of the head portion 121 of the protruding piece 120 is longer than the width WL of the second subsidiary through hole H2. Thus, the head portion 121 of the protruding piece 120 is unable to penetrate through the second subsidiary through hole H2, and the baffle structure 130 cannot be detached from the frame 110.

Furthermore, in this embodiment, as shown in FIGS. 1-2, 4 and 6, the baffle structure 130 further includes a buckling portion 133. The buckling portion 133 is configured to buckle with the frame 110. To be specific, the buckling portion 133 is connected with the first blocking plate 131. The first blocking plate 131 is at least partially located between the second blocking plate 132 and the buckling portion 133 along the first direction D1. For example, as shown in FIG. 6, the buckling portion 133 is at least partially of a hook shape. When the second blocking plate 132 abuts against the second surface 112 of the frame 110, the buckling portion 133 shaped as a hook can buckle with an edge 111a of the first surface 111. Thus, the position of the baffle structure 130 relative to the frame 110 along the first direction D1 is further secured.

During a practical operation, when the user is going to detach the baffle structure 130 from the frame 110, the user can first pull the buckling portion 133 shaped as a hook, such that the buckling portion 133 is no longer buckled with the edge 111a of the first surface 111. At this point, the user can move the baffle structure 130 relative to the frame 110 along the first direction D1, such that the second blocking plate 132 does not abut against the second surface 112 of the frame 110 anymore, and the rod portion 122 of the protruding piece 120 is shifted from the second subsidiary through hole H2 to the first subsidiary through hole H1. Thus, the head portion 121 of the protruding piece 120 aligns with the first subsidiary through hole H1. The head portion 121 of the protruding piece 120 then penetrates through the first subsidiary through hole H1, and the baffle structure 130 is detached from the frame 110.

In simple words, no additional tools are involved in the process to install the baffle structure 130 to the frame 110 or in the process to detach the baffle structure 130 from the frame 110. The user can easily finish these processes by his/her bare hands, which is convenient to the user.

In addition, no additional locking components such as screws are involved in the process to secure the baffle structure 130 to the frame 110. Apart from a saving of material cost, the time taken for the installation or the detachment of the baffle structure 130 is also reduced.

Furthermore, since the first blocking plate 131 of the baffle structure 130 abuts against the first surface 111 of the frame 110 and at least partially covers the opening OP, the expansion cards 200 located inside the frame 110 are protected and blocked by the first blocking plate 131. Therefore, the expansion cards 200 will not be loosened from the frame 110. Moreover, the first blocking plate 131 facilitates a better effect of wind guiding and heat dissipation to the expansion cards 200.

According to the actual situation, a quantity of the protruding piece 120 and a quantity of the through hole HT are respectively plural. For example, in this embodiment, as shown in FIGS. 1-2, 4 and 6, the quantity of the protruding piece 120 and the quantity of the through hole HT of the first blocking plate 131 are respectively two. However, this does not intend to limit the present disclosure.

In conclusion, when compared with the prior art, the aforementioned embodiments of the present disclosure have at least the following advantage:

(1) Since no additional tools are involved in the process to install the baffle structure to the frame or in the process to detach the baffle structure from the frame, the user can easily finish these processes by his/her bare hands, which is convenient to the user.

(2) Since no additional locking components such as screws are involved in the process to secure the baffle structure to the frame, apart from a saving of material cost, the time taken for the installation or the detachment of the baffle structure is also reduced.

(3) Since the first blocking plate of the baffle structure abuts against the first surface of the frame and at least partially covers the opening, the expansion cards located inside the frame are protected and blocked by the first blocking plate. Therefore, the expansion cards will not be loosened from the frame. Moreover, the first blocking plate facilitates a better effect of wind guiding and heat dissipation to the expansion cards.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A baffle assembly, comprising:
a frame configured to accommodate a plurality of expansion cards, the frame comprising a first surface and a second surface adjacent to the first surface, the first surface having an opening configured to allow the expansion cards to enter into the frame;
at least one protruding piece protruding from the first surface; and
a baffle structure, comprising:
a first blocking plate configured to abut against the first surface and at least partially cover the opening, the first blocking plate having at least one through hole extending along a first direction, the protruding piece at least partially penetrating through the through hole; and
a second blocking plate connected with the first blocking plate along the first direction and configured to abut against the second surface.

2. The baffle assembly of claim 1, wherein the first surface and the second surface form a first angle, the first blocking plate and the second blocking plate form a second angle, the first angle is substantially equal to the second angle.

3. The baffle assembly of claim 2, wherein the first angle and the second angle are respectively 90 degrees.

4. The baffle assembly of claim 1, wherein the first blocking plate and the second blocking plate are connected with each other along a connecting line, the connecting line extends along a second direction, the second direction is perpendicular to the first direction.

5. The baffle assembly of claim 1, wherein the through hole has a first subsidiary through hole and a second subsidiary through hole communicated with the first subsidiary through hole, the second subsidiary through hole is located between the first subsidiary through hole and the second blocking plate along the first direction, the first subsidiary through hole is at least partially a circular hole, the second subsidiary through hole is at least partially a long hole extending along the first direction.

6. The baffle assembly of claim 5, wherein the second subsidiary through hole has a width along a second direction perpendicular to the first direction, the first subsidiary through hole has a diameter, the diameter is longer than the width.

7. The baffle assembly of claim 6, wherein the protruding piece comprises a head portion and a rod portion, the rod portion is connected between the head portion and the frame, a first outer dimension of the head portion is shorter than the diameter and longer than the width, a second outer dimension of the rod portion is substantially equal to the width.

8. The baffle assembly of claim 1, wherein the baffle structure further comprises a buckling portion configured to buckle with the frame, the buckling portion is connected with the first blocking plate, and the first blocking plate is at least partially located between the second blocking plate and the buckling portion along the first direction.

9. The baffle assembly of claim 8, wherein the buckling portion is at least partially of a hook shape and is configured to buckle with an edge of the first surface.

10. The baffle assembly of claim 1, wherein a quantity of the protruding piece and a quantity of the through hole are respectively plural.
